(19) United States
(12) Patent Application Publication
(10) Pub. No.: US 2008/0214302 A1
(43) Pub. Date: Sep. 4, 2008

(54) BOARD, SUPPORTING STRUCTURE FOR BOARD, AND GAMING MACHINE HAVING THE SAME SUPPORTING STRUCTURE FOR BOARD

(75) Inventor: Hiroyuki NAGANO, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Aruze Corp., Koto-ku (JP)

(21) Appl. No.: 12/020,034

(22) Filed: Jan. 25, 2008

(30) Foreign Application Priority Data
Jan. 29, 2007 (JP) 2007-017632

(51) Int. Cl. A63F 9/24; H05K 7/00

(52) U.S. Cl. 463/31; 361/748

(57) ABSTRACT

To provide a supporting structure which can prevent electric contact failures of memories and a CPU caused by warping of a board. In a supporting structure for a board including a CPU, memories, and a connector for removably attaching the CPU and memories, provided on a plate-like main body, a warping preventive body 5 is arranged in contact with the back surface of the plate-like main body.

### RELATED APPLICATION

This application claims the priority of Japanese Patent Application No. 2007-017632 filed on Jan. 29, 2007, which is incorporated herein by reference.

### BACKGROUND OF THE INVENTION

1. Field of the Invention

The present invention relates to a board, a supporting structure for the board, and a gaming machine having the same supporting structure for the board.

2. Description of the Related Art

Conventionally, general gaming machines including various game machines to be installed in a game arcade or the like include, in a gaming machine main body, a board housing for housing a control board, a display unit for displaying images corresponding to game progress, and an operating unit to be operated by a player, and is provided with a gaming section in which the game progress is controlled by the control board.

A board housed in the board housing normally has a structure in which a CPU, memories, and a connector for removably attaching the CPU and memories are provided on the surface of a plate-like main body. A frame for supporting this board is provided in the board housing, and a board is attached within the frame.

Recently, because of environmental issues, etc., in many gaming machines, even if the game contents are changed, the gaming machine main body is reused, and the CPU and memories, etc., are constituted as a unit and they are removably attached to a control board via a connector.

For example, a structure in which a memory cartridge is removably attached in an upright state to a control board is disclosed (for example, refer to Japanese Laid-Open Patent Application No. 2006-187480).

However, the CPU and memories mounted on the control board are easily heated during use, and in particular, the CPU is heated to a considerably high temperature, so that in some cases, a cooling device with a fan or the like is mounted on the control board, however, according to an increase in data amount and an increase in speed of processing, the CPU or the like is more easily heated and the cooling device also tends to increase in size.

In such circumstances, the above-described heating and a weight increase according to mounting of the cooling device easily cause deformation such as warping of the plate-like main body of the control board, and in some cases, this deformation causes electric contact failures of the components such as the CPU and memories.

On the other hand, the control board is housed in a limited space of the board housing inside the gaming main body, so that for operability of maintenance, a constitution in which the control board is laid horizontally and can be drawn out of the gaming machine main body has been proposed.

However, in this constitution, in particular, at the time of replacement of the memory, etc., an external force is applied perpendicularly to the surface of the plate-like main body and more easily deforms the plate-like main body, and in addition, the weight of the control board also easily causes deformation such as warping, so that it is difficult to solve electric contact failures caused by deformation of the board.

### SUMMARY OF THE INVENTION

An object of the invention is to provide a board, a supporting structure for the board, and a gaming machine having the same supporting structure for the board which can solve the above-described problem.

(1) According to a supporting structure for a board of the invention, in a supporting structure for a board having a CPU, memories, and a connector for removably attaching the CPU and memories provided on the surface of a plate-like main body, a warping preventive body which prevents warping of the plate-like member is arranged in contact with the back surface of the plate-like main body.

(2) According to the invention, in the supporting structure for a board described in (1) above, the board is arranged along the horizontal direction and the warping preventive body is arranged so as to support the plate-like main body of the board from below.

(3) According to the invention, in the supporting structure for a board described in (1) above, the warping preventive body is arranged corresponding to an arranged position of the connector provided on the surface of the plate-like main body.

(4) According to the invention, the supporting structure for a board described in (1) above, includes a positioning portion for regulating an arranged position of the warping preventive body, wherein the warping preventive body formed in a band plate shape can be interposed at a predetermined position between the plate-like main body and a base member supporting the plate-like main body.

(5) According to the invention, in the supporting structure for a board described in (1) above, a convex portion is formed on the surface of the warping preventive body and the tip end of the convex portion is brought into contact with the back surface side at the arranged position of the connector on the plate-like main body.

(6) According to the invention, in the supporting structure for a board described in (1) above, convex portions formed of a pair of convex pieces opposed to each other while leaving a predetermined gap therebetween are formed on the surface of the warping preventive body, and tip ends of the convex portions are brought into contact with the back surface side on the arranged position of the connector on the plate-like main body.

(7) According to the invention, in a board having a CPU, memories, and a connector for removably attaching the CPU and memories provided on the surface of a plate-like main body, a warping preventive body in a band plate shape at least a part of which is brought into contact with the back surface of the plate-like main body to prevent warping of the plate-like main body is provided.

(8) According to the invention, in a gaming machine including: a board housing which houses a board having at least a CPU and memories mounted on the surface of a plate-like main body; and a gaming section which includes a display unit that displays images corresponding to game progress and an operating unit to be operated by a player, and in which game progress is controlled by the board, a base member supporting at least a peripheral edge of the board is provided inside the board housing, and within the base member, the board is arranged, and on the board, a warping preventive body for preventing warping of the plate-like main body is arranged in contact with the back surface of the plate-like main body.

Additional objects and advantage of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE INVENTION OF THE DRAWINGS

The accompanying drawings, which are incorporated in and constitute a part of the specification, illustrate embodiments of the invention, and together with the general description given above and the detailed description of the embodiments given below, serve to explain the principals of the invention.

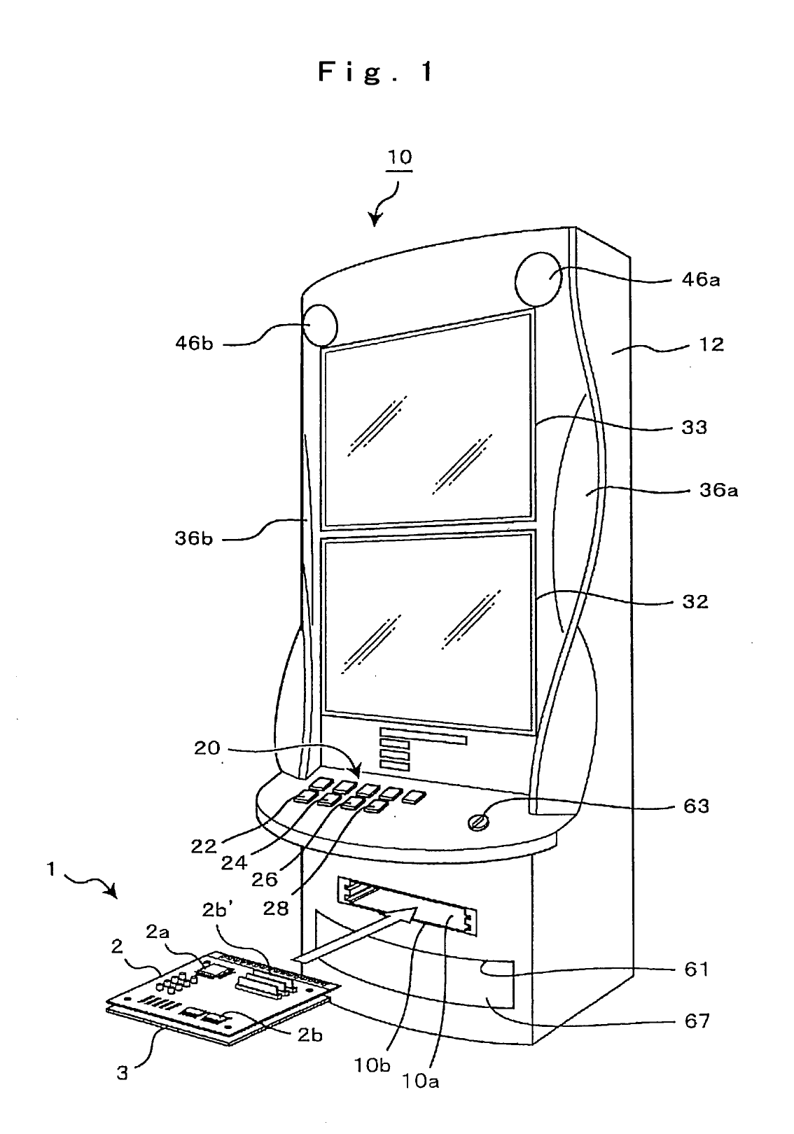

FIG. 1 is a perspective view of a gaming machine to which a board of an embodiment is fitted;

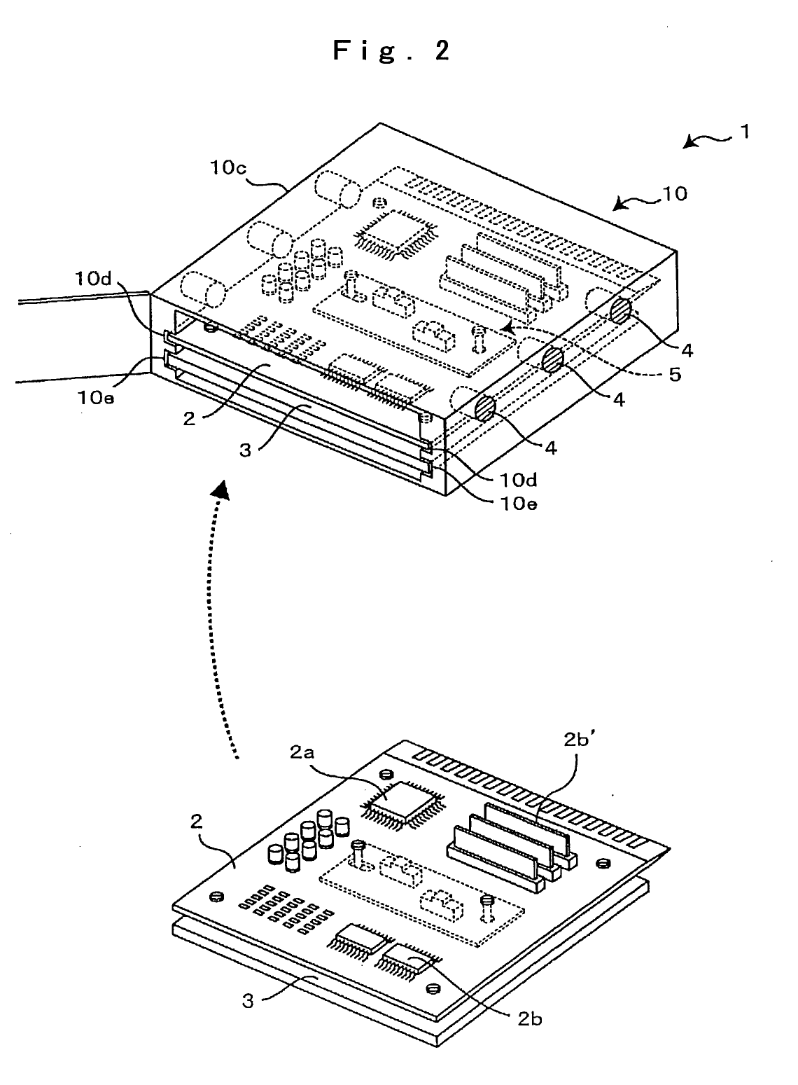

FIG. 2 is a perspective view of a board housing of a gaming machine including the same board installed inside, and the same board;

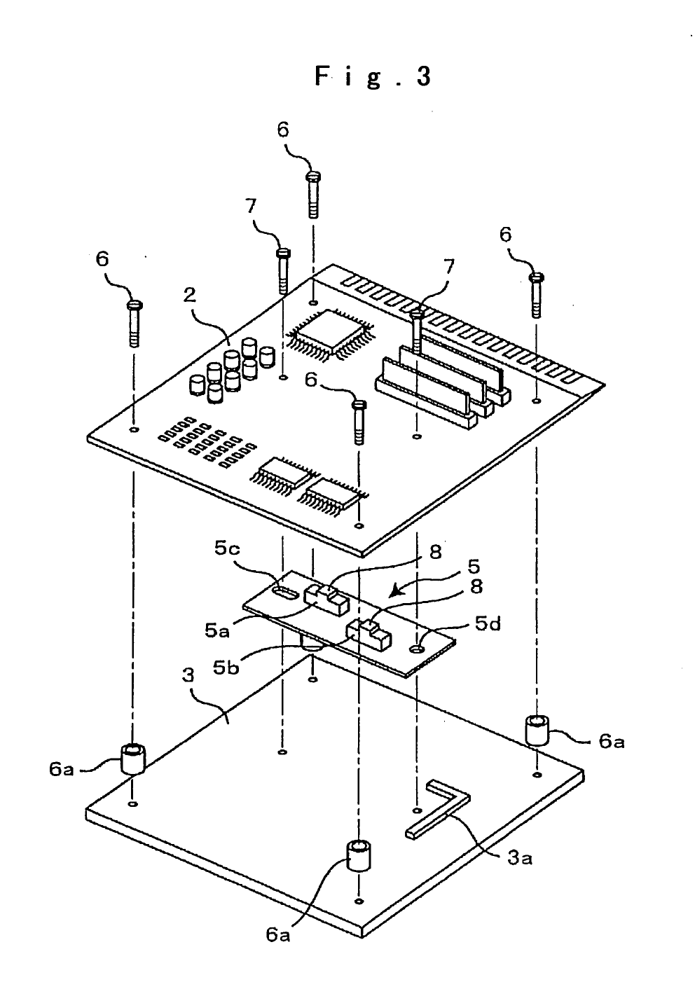

FIG. 3 is an exploded perspective view of a board arranged on a base board as a base member; and

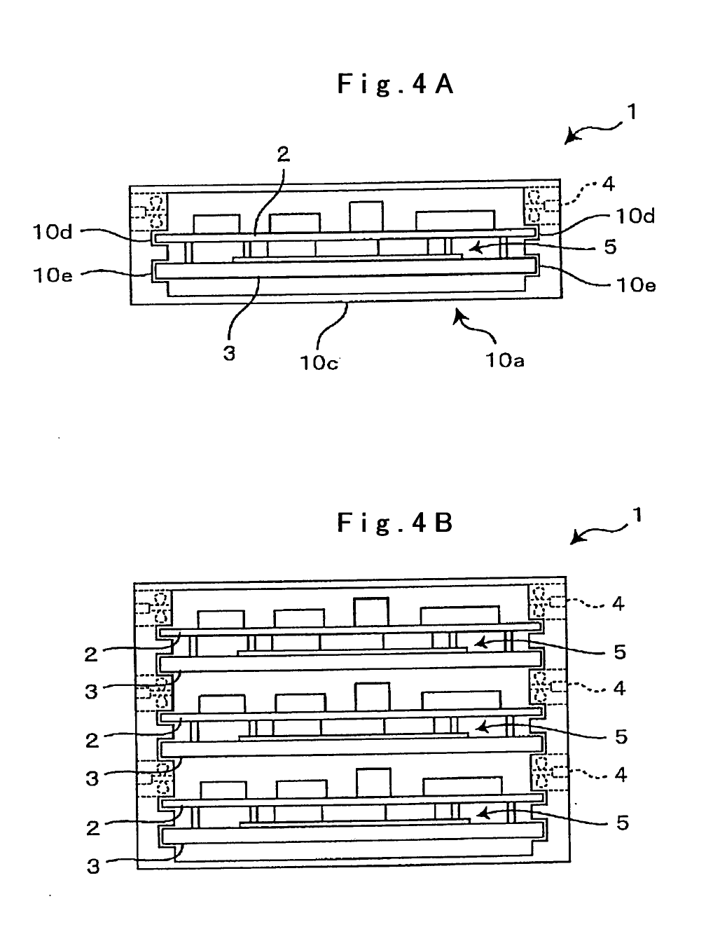

FIG. 4 are a sectional view of a board housing in which a board is housed and a sectional view of a variation thereof.

### DETAILED DESCRIPTION OF THE PREFERRED EMBODIMENTS

According to the invention, warping of a board can be prevented, so that electric contact failures of the memories and CPU caused by warping of the board can be prevented.

A board of this embodiment has, on the surface of a plate-like main body, a CPU, memories, and a connector for removably attaching the CPU and memories, wherein the board includes a warping preventive body in a band plate shape arranged so that at least a part thereof is brought into contact with the back surface of the plate-like main body to prevent warping of the plate-like main body. Accordingly, the board with a warping preventive body can be constituted, the mounting operability is excellent, and while working on this board, excellent durability against vibrations and excellent operation reliability are realized.

A supporting structure for the above-described board is constituted as follows.

Specifically, in a supporting structure for a board having a CPU, memories, and a connector for removably attaching the CPU and memories provided on the surface of a plate-like main body, a warping preventive body is arranged in a state that it is brought into contact with the back surface of the plate-like main body to prevent warping of the plate-like main body. By constituting the supporting structure provided with this warping preventive body, even if an external force in the perpendicular direction is applied or the weight of the control board is applied to the plate-like main body when replacing the mounted members such as the CPU and memories, deformation does not occur, so that troubles and failures such as electric contact failures caused by deformation of the board can be effectively prevented, and operation stability can be improved.

The board is constituted by attaching a plate-like main body on which a CPU, memories, and a connector for removably attaching the CPU and memories are provided to a base board as a base member, and the board is housed in a board housing of a gaming machine, etc.

The warping preventive body is a member arranged in contact with the back surface of a board having a CPU and memories mounted on the surface of a plate-like main body, and can be arbitrarily formed into a rectangular parallelepiped, disk shape, or the like from plastic, metal, rubber, or a composite material of these. The warping preventive body is interposed between a board that is mainly made of plastic and easily warps and a base member made of a high-rigidity material such as a metal via engagement members such as bolts and nuts or an adhesive means, and prevents warping that is easily caused by the weight of the board and a load applied when the memories, etc., are attached.

In the supporting structure for a board of this embodiment, the plate-like main body is laid horizontally, and the warping preventive body is arranged so as to support the plate-like main body from below.

In the supporting structure for a board of this embodiment, the warping preventive body is arranged corresponding to an arranged position of the connector provided on the surface of the plate-like main body.

Thereby, the warping preventive body can be attached in advance to the back surface of the board, and a mounting operation for attaching the board to the base member such as a base board can be efficiently performed without being conscious of warping, so that the productivity in manufacturing of a gaming machine with the board installed inside can be improved.

In the supporting structure for a board of this embodiment, the warping preventive body is formed into, for example, a rectangular band plate shape, and provided with a positioning portion for regulating an arranged position at an arbitrary position, and can be interposed at a predetermined position between the plate-like main body and the base member supporting the plate-like main body.

Thereby, the warping preventive body can be efficiently and reliably attached in the board mounting operation, and the manufacturing cost can be reduced.

The positioning portion is to be attached to a predetermined position between the plate-like main body and the base member supporting the plate-like main body via screws, machine screws, and pins, and can be formed integrally with the warping preventive body, however, it may be formed separately and attached to the warping preventive body.

In the supporting structure for a board of this embodiment, a convex portion is formed on the surface of the warping preventive body, and the tip end of this convex portion is brought into contact with the back surface side at the connector arranged position of the plate-like main body.

Accordingly, while effectively supporting the board, the warping preventive body can be prevented from coming into close contact with the board back surface, and heat radiation via the base member, etc., can be promoted.

The convex portion can be formed of a pair of convex pieces opposed to each other while leaving a predetermined gap therebetween.

Accordingly, for example, while efficiently holding a portion most likely to warp, an air flow path is formed between the convex pieces and an effective cooling air flow is formed between the board and the base member supporting the board to enable generated heat to be radiated, whereby the operation stability of the CPU mounted on the board can be improved.

In this embodiment, a gaming board having the above-described board and the supporting structure for the same can be provided.

Specifically, in a gaming machine including: a board housing which houses a board on which at least a CPU and memories are mounted; and a gaming section which includes a display unit for displaying images corresponding to game progress and an operating unit to be operated by a player, and by which the game progress is controlled by the board, a base member supporting the peripheral edge of the board is provided inside the board housing, and within the base member, the board is arranged and supported by the supporting structure for the board.

With this constitution, the stability and reliability of the board which is attached to a gaming machine such as a pachinko gaming machine or other gaming machine and controls games can be improved. In addition, electronic components such as the CPU arranged within the gaming machine can be collected on the board and this board is housed in a board housing and can be reliably protected from dust around the gaming machine. Further, normally, electrical connection of the board is made by inserting a connector connected to many electric wires into a connector of the board side. At the time of this insertion, a great force is applied to the circuit board side, however, by providing the warping preventive body, the board is prevented from greatly warping or being broken, and its operation stability can be secured.

The gaming machine may be, for example, a TV game machine using the display unit which performs a ball-bouncing game, poker game, and the like, and in such a gaming machine, a large number and many kinds of electronic components are mounted on a board via a connector. Electronic components used in this gaming machine include a CPU for controlling various mechanisms and memories for storing predetermined game programs. The memories store programs, etc., so as to display numerals with fixed probabilities, and are used for changing winning conditions of the gaming machine by the displayed numerals, etc.

The board housing is a member for housing a board to which the kinds of electronic components are fitted and a base member supporting the board, and includes a flat support plate to be fixed onto a flat surface of the gaming machine, and a box main body covering the support plate. In the board housing, an electronic component mounting circuit board or the like is fixed onto the support plate, and a lead wire from a connector of this circuit board is led out to the box main body and electrically connected to the gaming section described latex.

The display unit is a display such as a liquid crystal display device for displaying effect images relating to games and game information, etc.

For example, in the case of a ball-bouncing game, the display unit is provided on a gaming table, and has a display area capable of displaying images relating to games, and this display area has an effect image display area for displaying effect images corresponding to a game state so as to display various images such as decoration images for decoration as well as predetermined effect images. In the case of a poker game, card images and combinations of cards, and game scores corresponding to specific poker combinations of the card images are displayed.

The operating unit is a launching handle to be operated by a player in the case of a ball-bouncing game or the like, a card select button or a joystick in the case of a TV game.

The gaming section is an aggregation of a movable member for effects with which the game progress is controlled by the board, a sound generator such as a speaker or a buzzer, and a luminous unit such as a decoration lamp and a liquid crystal panel, and also includes the display unit such as a liquid crystal display device for displaying game information.

Hereinafter, with reference to the drawings, the embodiment of the invention will be described in greater detail.

FIG. 1 is a perspective view showing an external appearance of a gaming machine to which a board of this embodiment is attached, and FIG. 2 is a perspective view of a board housing of a gaming machine having the board installed inside and the board. FIG. 3 is an exploded perspective view of a board arranged on a base board as a base member.

A gaming machine 10 of an embodiment of the invention is a coin-operated arcade gaming machine which is installed in, for example, a game arcade or the like and performs a game in response to insertion of predetermined medals or the like as shown in FIG. 1, and for example, performs a poker game. Execution programs and data of the game in the gaming machine 10 are loaded in storage units such as memories mounted on a board 2. Then, as shown in FIG. 1, the board 2 is housed and fixed into a board housing 10a of the gaming machine 10 as a board unit 1 having a supporting structure described later, and can be attached and removed as appropriate through a board insertion opening 10b provided in the front side of the board housing 10a.

As shown in FIG. 1 through FIG. 3, the board unit 1 includes a board 2, a base board 3 on which the board 2 is mounted, a board housing 10a housing the board and the base board, and so on.

The board 2 formed of a circuit board or the like has a CPU 2a and memories 2b and 2b′, etc., mounted on the surface of a plate-like main body as a printed board mainly made of rigid plastic via a connector. In this embodiment, the memory 2b is a ROM and the memory 2b′ is a RAM. The four corners, etc., of the board 2 are fixed and overlapped onto the base board (base member) while leaving a predetermined gap therebetween by using engagement members such as machine screws 6 and spacers 6a.

In the supporting structure of the board 2 of this embodiment, a warping preventive body 5 formed into a substantially rectangular band plate shape is attached to the center of the back surface side of the board 2 on which the CPU 2a, etc., are mounted.

On this warping preventive body 5, two convex portions 5a and 5b formed into rectangular parallelepiped shapes are staggered so as to oppose each other to form a support, and by interposing the warping preventive body 5 between the base board 3 and the board 2, the weight and external force applied to the board center when the board is handled are received by the base board 3 from below. Therefore, warping of the board 2 due to its own weight according to aging, warping of the board 2 due to a load applied when the memory (2b′) (RAM) is additionally provided and inserted in the connector, and electric contact failures of components mounted on the board 2 resulting from the warping, can be prevented.

The convex portions 5a and 5b are formed integrally with the warping preventive body 5 in this embodiment, however, it is also allowed that, for example, members made of rubber or plastic, etc., is attached later to a predetermined position of the plate-like main body of the warping preventive body 5.

Further, in this embodiment, convex pieces 8 are formed on the contact surfaces of the convex portions 5a and 5b with the board 2, and the tip ends of the convex pieces 8 are brought into contact with the back surface side at the arranged position of the connector of the board 2.

Specifically, in the entire area between the convex portions 5a and 5b and between the convex pieces 8, an air flow path is formed so that a cooling air flow is formed between the board 2 and the base board 3 supporting the board 2, whereby the operation stability of the CPU mounted on the board 2 is improved.

At both ends of the warping preventive body 5, boss holes 5c and 5d into which bolts 7 to be attached to the base board 3 are inserted are made as an example of the positioning portion. One boss hole 5c is formed into a slot so that the attaching position of the warping preventive body 5 can be adjusted, and the other boss hole 5d is formed into a circular hole. In this embodiment, on the base board 3 onto which the warping preventive body 5 is attached, a board side positioning portion 3a for making easy the attachment of the warping preventive body 5 is provided, and this board side positioning portion 3a is formed into an L shape of a U shape and an end of the warping preventive body 5 can be fitted thereto.

FIG. 4(a) is a sectional view of the board housing 10a housing the board unit 1 consisting of the board 2 having the supporting structure including the base board 3 and the engagement members, and FIG. 4(b) is a sectional view of a board housing in a variation in which three board units 1 are laminated.

Similar to a personal computer motherboard generally available on the market, the CPU cooling device is also increased in size according to an increase in the speed of arithmetic operations of the CPU, and therefore, the board 2 warps due to aging or thermal breakdown, and operation errors due to contact failures occur among the connected memories, CPU, and board, etc. This phenomenon greatly depends on the installation environment of the game machine, and in particular, machines for overseas are greatly influenced by the surrounding temperature and dust.

That is, when the heating of the CPU according to an increase in the speed of data processing and an increased weight according to an increase in the size of the cooling device for cooling the CPU directly continuously influence the board of the motherboard, the board 2 warps. In this case, the board 2 serving as the motherboard is greatly waved around the CPU, the memories float from the connector, and warping that cannot be eliminated even by re-inserting the memories may occur.

In the gaming machine 10 of this embodiment, the board unit 1 is attached into the board housing 10a, and the board is provided with a supporting structure in which the warping preventive body 5 is arranged so as to support the area around the memories and connector which may easily cause operation errors from below.

As shown in FIG. 4(a), an air vent port 4 is made in the side wall of a fixing case 10c of the board housing 10a so that an air flow is formed inside the fixing case 10c to cool the inside of the fixing case 10c.

Generally, depending on the fixing method for the board 2, in the type of fixation with machine screws, the fixing bosses thereof can be used for positioning and the shapes can be devised so that the machine screws come to positions with less wiring so as not to damage the delicate wiring of the motherboard. Further, the number of machine screws is minimized so as to increase the space for radiating the heat of the board as large as possible.

Thus, as shown in FIG. 2 and FIG. 4, the left and right sides of the board 2 and the base board 3 can be sandwiched and fixed inside grooves 10d and 10e provided on the side walls of the fixing case 10c. Therefore, without requiring special fixing parts, a plurality of boards are stacked and the mounting density of the boards can be improved.

Hereinafter, the constitution of the gaming machine 1 shown in FIG. 1 will be further described.

As illustrated, on the central front face of the gaming machine 10, a first display 32 as an example of the display unit is provided. Above the first display 32 on the front face of the gaming machine 10, a second display 33 (display unit) is provided. On the first display 32, cards dealt to a player and a payout table showing winning combinations of the cards are displayed. On the second display 33, effect images are displayed. The first display 32 and the second display 33 are touch-sensitive liquid crystal displays.

Near the right of the front face of the gaming machine 10, a medal insertion slot 63 is provided, and the lower side of the front face, a medal payout opening 61 and a medal receiving portion 67 are provided. When a player inserts medals into the medal insertion slot 63, gaming is enabled. Inside the gaming machine 10, a medal detection sensor that is not shown is installed and detects insertion of medals into the gaming machine 10 by a player. According to a game result, medals are paid out from the medal payout opening 61, and stored in the medal receiving portion 67.

By the side of the gaming machine 10, decoration lamps 36a and 36b are provided, and at the upper side of the gaming machine 10, speakers 46a and 46b are provided. The decoration lamps 36a and 36b are turned on or flash at predetermined intervals according to the game progress. The speakers 46a and 46b produce predetermined effect sounds along with the game progress.

Below the first display 32, an operating unit on which various switches described below to be used for advancing the game are arranged is provided like a table.

In the figure, the reference numeral 26 denotes a MAX switch, and 28 denotes a BET-ONE switch, and these are used by a player to start a game. The BET-ONE switch 28 increases the number of medals to be inserted for a game according to the number of depressions on this switch. The BET-MAX switch 26 is used for betting five, that is, in this embodiment, a maximum number of medals at a time.

On the left of the BET-MAX switch 26, a DEAL switch 24 and a CASH-OUT switch 22 are arranged. On the upper side of the BET-MAX switch 26, five HOLD switches 20 are arranged.

The DEAL switch 24 is used by a player to display cards. After a player performs a medal inserting operation, by depressing the DEAL switch 24, images of dealt cards or changed new cards are displayed on the first display 32.

The CASH-OUT switch 22 is used to refund medals saved (credited) in the gaming machine 10. When a player depresses and turns ON the CASH-OUT switch 22, medals are paid out into the medal receiving portion 67.

A total of five HOLD switches 20 are provided. The HOLD switches 20 are arranged corresponding to the respective images of the cards displayed on the first display 32. The HOLD switches 20 are used by a player to select a card which the player does not change but leaves after the cards are displayed. When a player depresses and turns-ON a HOLD switch 20 under a card that the player selected among the five cards displayed on the first display 32, the selected card is not changed but is left.

The gaming machine 10 of this embodiment uses medals as game media, however, it may be a game machine using coins, tokens, a card storing information on game values, or the like.

As described above, the point of the gaming machine 10 of this embodiment is that a supporting structure including the spacer-like warping preventive body 5 arranged so as to support the surrounding of the memories and connector that may cause operation errors in the board 2 controlling the game program, etc., from below, is attached to the board housing 10a. Thereby, electric contact failures of the memories, CPU, and connector can be prevented.

In other words, by arranging the warping preventive body 5 between the board 2 and the base board 3, the board is held so as not to warp even when heating of the CPU 2a, etc., according to an increase in the speed of data processing in the board 2 and a weight of a cooling device for cooling the CPU 2a being directly applied to the board 2.

In the board housing 10a of the gaming machine 10, the supporting structure is minimized so as to increase the heat radiation space for the board 2 as large as possible, and without requiring special fixing parts, the board 2 is sandwiched and fixed between side walls of the fixing case 10c of the board housing 10a. Further, the weight of the board 2 is evenly applied to the surface of the base board 3, so that when mounting the board, position deviation of the board 2 can be reduced as in the case of the normal horizontal placing and vertical placing, and the mounting operation efficiency can be improved.

Further, by arranging the base board on the back surface side of a flexible board and arranging insertion ends of boss holes into which engagement members such as bolts or machine screws are inserted on the back surface side, the board is fixed to the base board, so that this fixing operation is easy and fixing strength is improved.

In addition, by applying the board supporting structure to the board 2 that has already warped, an effect of correcting the warping of the board 2 can be obtained. Thus, when a connector connected to many cables is inserted into the board side connector, this board is supported by the warping preventive body 5 serving as a support, so that the board is prevented from being warped and broken, and troubles such as electric connection failures and disconnection on the board can be prevented.

In the state that the board 2 and the base board 3 are fitted to each other, an air vent port 4 is made in the side face of the fixing case 10c of the board housing 10a, so that an excellent cooling effect is obtained, and a control device with excellent operation reliability is obtained.

Further, when a pulling force or a bending stress is applied to the flexible board 2, such a stress is applied to only the periphery of the boss holes in slot shapes or the base board 3, and in addition, by making the convex portions 5a and 5b of the warping preventive body 5 of an elastic material such as rubber, mechanical impact thereon can be absorbed, so that disconnection can be prevented and excellent durability can be obtained.

Even when a plurality of boards 2 are stacked (see FIG. 4(b)), they can be easily removed from the board housing 10a, and a metal exposed portion can be separated at a predetermined distance from the pattern surface of each board, so that the boards are hardly influenced by static electricity, etc.

An embodiment of the invention is described above, however, the effects described in the embodiment of the invention are only a list of the most preferred effects of the present invention, and the effects of the present invention are not limited to those described in the embodiment of the present invention.

The point of the present invention is that a warping preventive body is provided on the back surface of a board to prevent deformation of the board, and techniques corresponding to this fall within the scope of the right of the present invention. For example, in the embodiment, the present invention is applied to a poker game machine as an example of a gaming machine, however, the present invention is also applicable to a pachi-slot machine or a pachinko gaming machine, etc.

The convex pieces 8 are provided on the contact surfaces of the convex portions 5a and 5b to come into contact with the board 2, however, these convex pieces 8 may be disused.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A supporting structure for a board having a CPU, memories, and a connector for removably attaching the CPU and memories provided on the surface of a plate-like main body, wherein
a warping preventive body which prevents warping of the plate-like main body is arranged in contact with the back surface of the plate-like main body.

2. The supporting structure for a board according to claim 1, wherein
the board is arranged along the horizontal direction and the warping preventive body is arranged so as to support the plate-like main body of the board from below.

3. The supporting structure for a board according to claim 1, wherein the warping preventive body is arranged corresponding to an arranged position of the connector provided on the surface of the plate-like main body.

4. The supporting structure for a board according to claim 1, comprising a positioning portion for regulating an arranged position of the warping preventive body, wherein the warping preventive body formed in a band plate shape can be interposed at a predetermined position between the plate-like main body and a base member supporting the plate-like main body.

5. The supporting structure for a board according to claim 1, wherein a convex portion is formed on the surface of the warping preventive body, and the tip end of the convex portion is brought into contact with the back surface side at the arranged position of the connector on the plate-like main body.

6. The supporting structure for a board according to claim 1, wherein convex portions formed of a pair of convex pieces opposed to each other while leaving a predetermined gap therebetween are formed on the surface of the warping preventive body, and tip ends of the convex portions are brought into contact with the back surface side on the arranged position of the connector on the plate-like main body.

7. A board having a CPU, memories, and a connector for removably attaching the CPU and memories provided on the surface of a plate-like main body, comprising:
a warping preventive body in a band plate shape at least a part of which is brought into contact with the back surface of the plate-like main body to prevent warping of the plate-like main body.

8. A gaming machine comprising:
a board housing which houses a board having at least a CPU and memories mounted on the surface of a plate-like main body; and
a gaming section which includes a display unit that displays images corresponding to game progress and an operating unit to be operated by a player, and in which game progress is controlled by the board, wherein
a base member supporting at least a peripheral edge of the board is provided inside the board housing, and within the base member, the board is arranged, and on the board, a warping preventive body for preventing warping of the plate-like main body is arranged in contact with the back surface of the plate-like main body.
